(19) United States
(12) Patent Application Publication
(10) Pub. No.: US 2022/0157709 A1
(43) Pub. Date: May 19, 2022

(54) SEMICONDUCTOR PACKAGE STRUCTURE AND METHOD FOR MANUFACTURING THE SAME

(71) Applicant: Advanced Semiconductor Engineering, Inc., Kaohsiung (TW)

(72) Inventors: Hsu-Chiang Shih, Kaohsiung (TW); Meng-Wei Hsieh, Kaohsiung (TW); Hung-Yi Lin, Kaohsiung (TW); Cheng-Yuan Kung, Kaohsiung (TW)

(73) Assignee: Advanced Semiconductor Engineering, Inc., Kaohsiung (TW)

(21) Appl. No.: 16/951,936

(22) Filed: Nov. 18, 2020

(51) Int. Cl. H01L 23/522; H01L 23/00; H01L 23/528; H01L 23/31; H01L 27/08; H01L 21/768; H01L 21/78

(52) U.S. Cl. CPC H01L 23/5226; H01L 24/14; H01L 23/528; H01L 21/78; H01L 27/0805; H01L 21/76877; H01L 21/76802; H01L 23/31

(57) ABSTRACT

A semiconductor package structure and method for manufacturing the same are provided. The semiconductor package structure includes a first electronic component, a conductive pillar, a second electronic component, and a conductive through via. The conductive pillar is disposed on the first electronic component and has a first surface facing away from the first electronic component. The second electronic component is disposed on the first electronic component. The conductive through via extends through the second electronic component and has a first surface facing away from the first electronic component. The first surface of the conductive through via and the first surface of the conductive pillar are substantially coplanar.

### BACKGROUND

### 1. Field of the Disclosure

The present disclosure relates to semiconductor package structures and manufacturing methods, and in particular, to a semiconductor package structure including a plurality of electronic components and a method for manufacturing the same.

### 2. Description of the Related Art

A semiconductor package structure may include an electronic component disposed on a substrate. The electronic component may be provided from a singulation of a wafer. Extra electrical connection elements may be formed on the frontside surface and the backside surface of the electronic component before the singulation of the wafer. Such extra electrical connection elements can protrude from the frontside surface and the backside surface, causing those surfaces to become uneven. The surfaces being uneven cause the risk of cracks in the wafer to be higher during the singulation process. Furthermore, the relatively long electrical path established among these electrical connections and the circuit layer of the electronic component may result in worse signal latency and increased power consumption.

### SUMMARY

In some embodiments, a semiconductor package structure includes a first electronic component, a conductive pillar, a second electronic component, and a conductive through via. The conductive pillar is disposed on the first electronic component and has a first surface facing away from the first electronic component. The second electronic component is disposed on the first electronic component. The conductive through via extends through the second electronic component and has a first surface facing away from the first electronic component. The first surface of the conductive through via and the first surface of the conductive pillar are substantially coplanar.

In some embodiments, a manufacturing method includes providing a semiconductor package structure. The semiconductor package structure includes a first electronic component, a conductive pillar on the first electronic component, a second electronic component on the first electronic component, and an encapsulant surrounding the conductive pillar and the second electronic component. The second electronic component has a conductive through via extending therethrough. The method further includes thinning the encapsulant, the conductive pillar, and the second electronic component in a same direction.

### BRIEF DESCRIPTION OF THE DRAWINGS

Aspects of some embodiments of the present disclosure are readily understood from the following detailed description when read with the accompanying figures. It is noted that various structures may not be drawn to scale, and dimensions of the various structures may be arbitrarily increased or reduced for clarity of discussion.

FIG. 1 illustrates a cross-sectional view of a semiconductor package structure according to some embodiments of the present disclosure.

FIG. 2 illustrates a cross-sectional view of a semiconductor package structure according to some embodiments of the present disclosure.

FIG. 3 illustrates a cross-sectional view of a semiconductor package structure according to some embodiments of the present disclosure.

FIG. 4 illustrates a cross-sectional view of a semiconductor package structure according to some embodiments of the present disclosure.

FIG. 5 illustrates a cross-sectional view of a semiconductor package structure according to some embodiments of the present disclosure.

FIG. 6 illustrates a cross-sectional view of a semiconductor package structure according to some embodiments of the present disclosure.

FIG. 7 illustrates a cross-sectional view of a semiconductor package structure according to some embodiments of the present disclosure.

FIG. 8 illustrates one or more stages of an example of a method for manufacturing a semiconductor package structure according to some embodiments of the present disclosure.

FIG. 9 illustrates one or more stages of an example of a method for manufacturing a semiconductor package structure according to some embodiments of the present disclosure.

FIG. 10 illustrates one or more stages of an example of a method for manufacturing a semiconductor package structure according to some embodiments of the present disclosure.

FIG. 11 illustrates one or more stages of an example of a method for manufacturing a semiconductor package structure according to some embodiments of the present disclosure.

FIG. 12 illustrates one or more stages of an example of a method for manufacturing a semiconductor package structure according to some embodiments of the present disclosure.

FIG. 13 illustrates one or more stages of an example of a method for manufacturing a semiconductor package structure according to some embodiments of the present disclosure.

FIG. 14 illustrates one or more stages of an example of a method for manufacturing a semiconductor package structure according to some embodiments of the present disclosure.

FIG. 15 illustrates one or more stages of an example of a method for manufacturing a semiconductor package structure according to some embodiments of the present disclosure.

FIG. 16 illustrates one or more stages of an example of a method for manufacturing a semiconductor package structure according to some embodiments of the present disclosure.

FIG. 17 illustrates one or more stages of an example of a method for manufacturing a semiconductor package structure according to some embodiments of the present disclosure.

FIG. 18 illustrates one or more stages of an example of a method for manufacturing a semiconductor package structure according to some embodiments of the present disclosure.

FIG. 19 illustrates one or more stages of an example of a method for manufacturing a semiconductor package structure according to some embodiments of the present disclosure.

FIG. 20 illustrates one or more stages of an example of a method for manufacturing a semiconductor package structure according to some embodiments of the present disclosure.

FIG. 21 illustrates one or more stages of an example of a method for manufacturing a semiconductor package structure according to some embodiments of the present disclosure.

FIG. 22 illustrates one or more stages of an example of a method for manufacturing an electronic device according to some embodiments of the present disclosure.

FIG. 23 illustrates a cross-sectional view of a semiconductor package structure according to some embodiments of the present disclosure.

FIG. 24 illustrates a cross-sectional view of a semiconductor package structure according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

The following disclosure provides many different embodiments, arrangements, or examples, for implementing different features of the provided subject matter. Specific examples of components and arrangements are described below to explain certain features of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, various different embodiments, examples, or arrangements may use a same reference numeral or letter to refer to a same or similar element for the purpose of clarity. Similarly shaded elements correspond to the same type of elements, although some of these elements may not be indicated using a reference numeral for the sake of clarity.

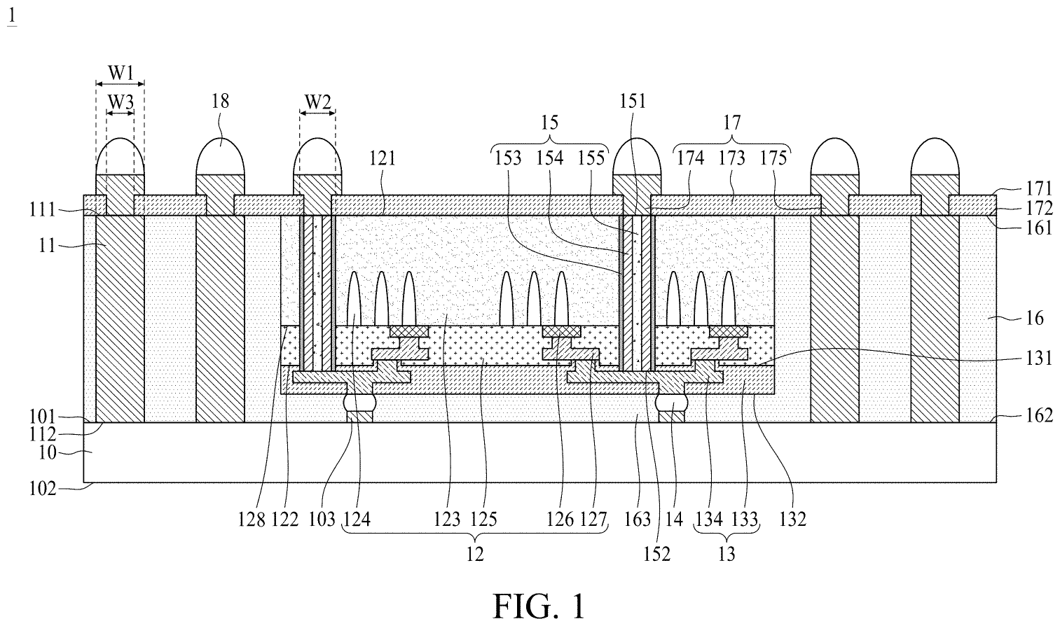

FIG. 1 illustrates a cross-sectional view of a semiconductor package structure 1 according to some embodiments of the present disclosure. The semiconductor package structure 1 includes an electronic component 10, a plurality of conductive pillars 11, an electronic component 12, a circuit layer 13, a plurality of electrical connection elements 14, a conductive through-via 15, an encapsulant 16, a circuit layer 17, and a plurality of electrical connection elements 18.

The electronic component 10 may have a surface 101 and a surface 102 opposite to the surface 101. In some embodiments, the electronic component 10 may be a chip or a die including a semiconductor substrate, one or more integrated circuit devices, and one or more overlying interconnection structures therein. The integrated circuit devices may include active devices (such as transistors) and/or passive devices such (resistors, capacitors, inductors, or a combination thereof). For example, the electronic component 10 may include, for example, one or more of a processor, logic die, application specific integrated circuit (ASIC), an input/output device, etc.

The plurality of conductive pillars 11 may be disposed on the surface 101 of the electronic component 10. The conductive pillar 11 may include a surface 111 facing away from the electronic component 10 and a surface 112 facing toward the electronic component 10. In some examples, the surface 112 abuts or contacts the surface 101 of the electronic component 10 as shown. Each of the plurality of conductive pillars 11 may be electrically connected to the electronic component 10, e.g., a plurality of conductive pads (not shown) of the electronic component 10. The material of the conductive pillar 11 may include, for example, metal such as copper, aluminum, gold, and/or other suitable materials.

The electronic component 12 may be disposed on the surface 101 of the electronic component 10. The electronic component 12 is disposed adjacent to the conductive pillar 11. The electronic component 12 and the conductive pillar 11 are disposed side by side. As shown, the electronic component 12 can be disposed between two or more adjacent conductive pillars 11. The electronic component 12 may have a surface 121 facing away from the electronic component 10 and a surface 122 facing toward the electronic component 10. In some embodiments, the electronic component 12 may be a chip or a die including a semiconductor substrate, one or more integrated circuit devices and one or more overlying interconnection structures therein. The integrated circuit devices may include active devices (such as transistors) and/or passive devices (such resistors, capacitors, inductors, or a combination thereof). For example, the electronic component 12 may include, for example, a de-coupling circuit, a memory device, etc.

The electronic component 12 may include a body 123 and a plurality of capacitors 124, a passivation layer 125, a plurality of conductive pads 126, and a plurality of conductive layers 127. The capacitors 124 may be disposed in the body 123. That is, the body 123 may encapsulate at least a portion of the capacitors 124. The passivation layer 125 may be disposed on the body 123. The conductive pads 126 and the conductive layers 127 may be disposed in the passivation layer 125. In some examples, the conductive pads 126 and the conductive layers 127 may be between two opposing surfaces of the passivation layer 125. The capacitor 124 may be electrically connected to the conductive pad 126 and/or the conductive layer 127. The capacitors 124 may include deep trench capacitors. The capacitors 124 may include a metal-dielectric laminate structure. The body 123 may have a backside surface, i.e., the surface 121, facing away from the electronic component 10. The body 123 may have a surface 128 facing toward the electronic component 10 and the surface 128 may be an active surface. The capacitor 124 may be adjacent to surface 128 of the body 123 of the electronic component 12. In some examples, the capacitor 124 is closer to the surface 128 than to the surface 121. The conductive pads 126 may be the electrodes of the capacitors 124. Further, the body 123 may include a plurality of electrical contacts (not shown) disposed adjacent to the surface 128 for electrical connection.

The circuit layer 13 (e.g., a built-up circuit layer) is disposed on the surface 122 of the electronic component 12. The circuit layer 13 is disposed between the electronic component 10 and the electronic component 12. The circuit layer 13 may have a surface 131 facing away from the electronic component 10 and a surface 132 facing toward the electronic component 10. The circuit layer 13 may include a passivation layer 133 and a plurality of conductive layers 134. The circuit layer 13, e.g., the conductive layers 134 of the circuit layer 13, may be electrically connected to the capacitors 124 through the conductive pads 126 and/or the conductive layers 127. The circuit layer 13, e.g., the conductive layers 134 of the circuit layer 13, may be electrically connected to a plurality of conductive pads 103 of the electronic component 10 through the plurality of electrical connection elements 14. In other words, the capacitors 124 may be electrically connected to the electronic component 10 through the circuit layer 13.

The material of the body 123 may include, for example, silicon, doped-silicon, silicon-oxide, or silicon-nitride or other semiconductor materials. The body 123 may include, for example, active devices (such as transistors) and/or passive devices (such resistors, capacitors, inductors, or a combination thereof). The material of the capacitors 124 may include a dielectric (such as oxide) and/or a conductive material (such as polysilicon or metal). The material of the passivation layer 125 and the passivation layer 133 may each include, for example, a molding compound, pre-impregnated composite fiber, borophosphosilicate (BPSG), silicon oxide, silicon oxynitride or the like. The material of the conductive pad 126, conductive layer 127, and the conductive layer 134 may each include, for example, metal such as copper, aluminum, gold, and/or other suitable materials. The electrical connection element 14 may include, for example, a solder ball or a controlled collapse chip connection (C4) bump.

Still referring to FIG. 1, the conductive through-via 15 may extend through the electronic component 12. For example, the conductive through-via 15 may fully penetrate the electronic component 12. The conductive through-via 15 may extend through an interface between the body 123 and the passivation layer 125. The interface therebetween and the surface 128 may be substantially coplanar. The conductive through-via 15 may be in contact with the conductive layer 134 of the circuit layer 13. The conductive layer 134 may be served as an etch stop layer for the conductive through via 15. The conductive through-via 15 may include a passivation layer 153, a conductive layer 154, and an insulation layer 155. The passivation layer 153 may be disposed along a sidewall of the conductive through-via 15. The conductive layer 154 may be surrounded by the passivation layer 153. The insulation layer 155 may be surrounded by the conductive layer 154. One or more of the passivation layer 153, the conductive layer 154, or the insulation layer 155 may have an end in contact with the conductive layer 134 of the circuit layer 13. The material of the passivation layer 153 may include, for example, dielectric material, such as polyamide (PA), polyimide (PI) or the like. The material of the conductive layer 154 may include, for example, metal such as copper, aluminum, gold, titanium, and/or other suitable materials. The material of the insulation layer 155 may include, for example, dielectric material, such as polyimide (PI) or the like.

The conductive through-via 15 may have a surface 151 facing away from the electronic component 10 and a surface 152 facing toward the electronic component 10. The passivation layer 153, the conductive layer 154, and the insulation layer 155 may each occupy a section of the surface 151 of the conductive through-via 15.

The encapsulant 16 is disposed on the surface 101 of the electronic component 10. The encapsulant 16 may have a surface 161 facing away from the electronic component 10 and a surface 162 facing toward the electronic component 10. The encapsulant 16 may surround the electronic component 12 and the conductive pillars 11. The surface 121 of the electronic component 12 may be exposed from the encapsulant 16. The surface 121 of the electronic component 12 and the surface 161 of the encapsulant 16 may be substantially coplanar. The surface 111 of the conductive pillar 11 and the surface 161 of the encapsulant 16 may be substantially coplanar. Furthermore, the surface 161 of the encapsulant 16 may be substantially at the same elevation relative to a reference plane (e.g., the surface 101) with the surface 151 of the conductive through via 15. The surface 121 of the electronic component 12 and the surface 151 of the conductive through-via 15 may be substantially coplanar. The surface 121 of the electronic component 12 and the surface 111 of the conductive pillar 11 may be substantially coplanar. The surface 151 of the conductive through-via 15 and the surface 111 of the conductive pillar 11 may be substantially coplanar. In some embodiments, a roughness of the surface 151 of the conductive pillar 15 and a roughness of the surface 111 of the conductive pillar 11 may be substantially the same. The roughness of a surface as discussed can be measured on the micro-(μm) and nanometer scales (nm) by atomic force microscopy (AFM) or other suitable surface roughness measurement processes. The roughness of a surface as discussed may include an average surface roughness (Rₐ), a RMS surface roughness (R_{q}), maximum surface roughness (Rₘₐₓ), etc.

The circuit layer 17 (e.g., a built-up circuit layer) is disposed on the conductive pillar 11, the electronic component 12, the conductive through-via 15, and/or the encapsulant 16. The circuit layer 17 may have a surface 172 shaped to conform to the substantially coplanar surfaces (e.g., the surfaces 111, 121, 151, and 161). The substantially coplanar surfaces (e.g., the surfaces 111, 121, 151, and 161) may facilitate the formation of the circuit layer 17 on the electronic component 12 and the encapsulant 16. Since there is no height difference among the substantially coplanar surfaces, it is possible to skip formation of an extra structure (e.g., extra electrical connections) thereon to compensate for height difference before forming the circuit layer 17.

The circuit layer 17 may include a passivation layer 173, a plurality of conductive layers 174, and a plurality of conductive layers 175. The conductive layers 174, 175 may each be disposed in the passivation layer 173 and may each include a protruding portion on a surface 171 of the circuit layer 17 opposite to the surface 172 and facing away from the electronic component 12. One of the electrical connection elements 18 may be electrically connected to the conductive through-via 15 through the conductive layer 174 of the circuit layer 17. Meanwhile, one of the electrical connection elements 18 may be electrically connected to the conductive pillar 11 through the conductive layer 175 of the circuit layer 17. Different connection structures, i.e., the conductive pillar 11 and the conductive through-via 15, of the semiconductor package structure 1 may be electrically connected to external circuitry through a common circuit layer (e.g., the circuit layer 17). In some embodiments, the connection element 18 is substantially aligned with the conductive through via 15 in the direction perpendicular to the surface 151 of the conductive through via 15 or the conductive pillar 11 in the direction perpendicular to the surface 111 of the conductive pillar 11.

Conventionally, a semiconductor package structure may include a substrate and an electronic component disposed on the substrate. Extra electrical connections on the backside surface of an electronic component are necessary, such that top surfaces of the extra electrical connections can be at the same elevation relative to a reference plane (e.g., a top surface of the substrate) as the top surfaces of some connection structures (e.g., a conductive pillar) disposed on the substrate. As a result, the total thickness (or the total height) of the semiconductor package structure is relatively large, and the electrical transmission path is relatively long. To address such issues, arrangements disclosed herein relate to a semiconductor package structure (e.g., the semiconductor package structure 1) having a common circuit layer (e.g., the circuit layer 17) that can bypass forming extra electrical connections on the backside of the electronic component 12. In that regard, the semiconductor package structure 1 has a smaller thickness (or a shorter height). Furthermore, the electrical transmission path established among the electronic components and external circuitry can be shortened.

Still referring to FIG. 1, the encapsulant 16 may include a portion 163 between the electronic component 10 and the electronic component 12. The encapsulant 16 may include, for example, an epoxy resin having fillers, a molding compound (e.g., an epoxy molding compound or other molding compound), a polyimide, a phenolic compound or material, a material with a silicone dispersed therein, or a combination thereof.

The material of the passivation layer 173 may include, for example, a molding compound, pre-impregnated composite fiber, borophosphosilicate (BPSG), silicon oxide, silicon oxynitride, or the like. The material of the conductive layers 174, 175 may each include, for example, metal such as copper, aluminum, gold, and/or other suitable materials. The electrical connection element 18 may include, for example, a solder ball or a controlled collapse chip connection (C4) bump.

Again referring to FIG. 1, a width W1 of the conductive pillar 11 may be greater than a width W3 of the conductive layer 175 (e.g., a conductive via) of the circuit layer 17. The width W1 of the conductive pillar 11 may be greater than a width W2 of the conductive through-via 15. In some examples, a dimension by which the width W1 of the conductive pillar 11 is measured, a dimension by which the width W2 of the conductive through-via 15 is measured, and a dimension by which the width W3 of the conductive layer 175 is measure are parallel to one another.

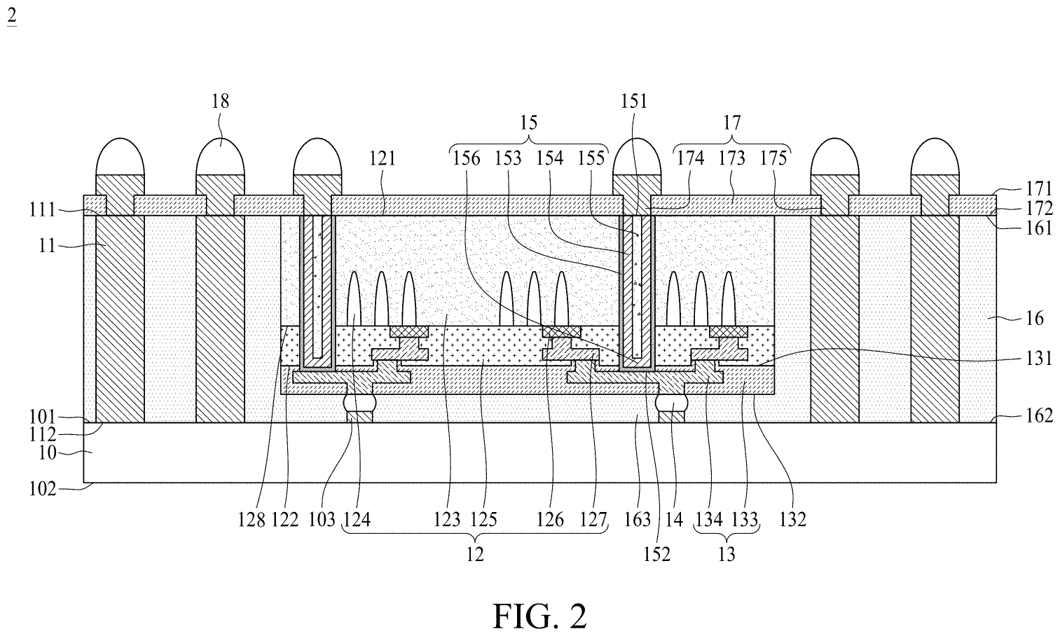

FIG. 2 illustrates a cross-sectional view of a semiconductor package structure 2 according to some embodiments of the present disclosure. The semiconductor package structure 2 is similar to the semiconductor package structure 1 of FIG. 1, except that the conductive through-via 15 further includes a portion 156 adjacent to the surface 152 of the conductive through-via 15. The portion 156 may include a conductive layer and a passivation layer disposed between the conductive layer of the portion 156 and the conductive layer 134 of the circuit layer 13. Thus, the insulation layer 155 may be free from contact with the conductive layer 134 of the circuit layer 13.

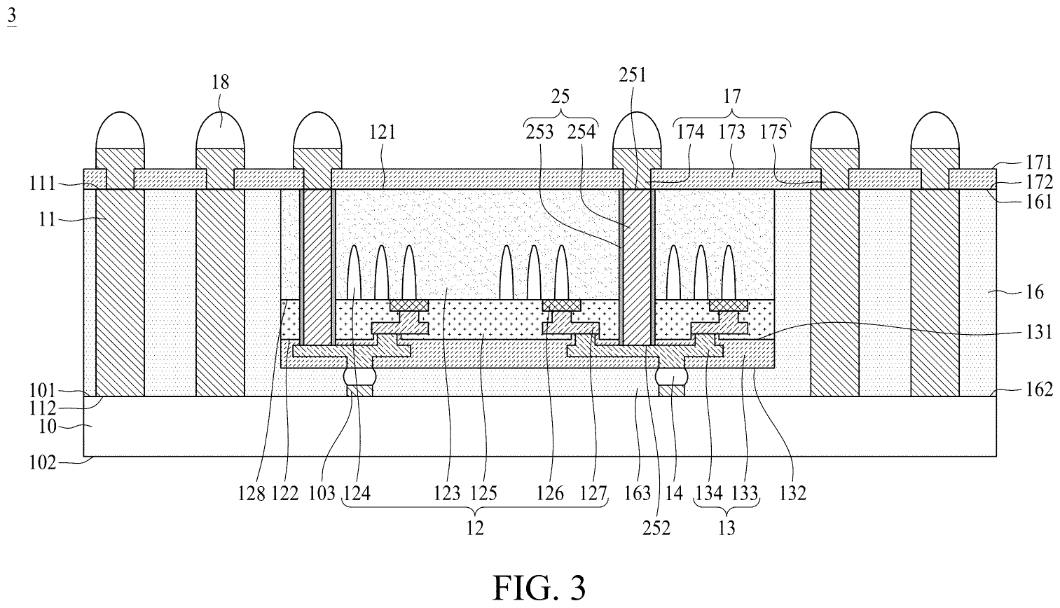

FIG. 3 illustrates a cross-sectional view of a semiconductor package structure 3 according to some embodiments of the present disclosure. The semiconductor package structure 3 is similar to the semiconductor package structure 1 of FIG. 1, except that the semiconductor package structure 3 includes a conductive through-via 25, instead of the conductive through-via 15 as illustrated in FIG. 1. The conductive through-via 25 may have a surface 251 facing away from the electronic component 10 and a surface 252 facing toward the electronic component 10. The surface 251 of the conductive through-via 25 and the surface 111 of the conductive pillar 11 may be substantially coplanar. The conductive through-via 25 may include an insulation layer 253 and a conductive layer 254. The insulation layer 253 may be disposed along a sidewall of the conductive through-via 25. The conductive layer 254 may fill in the space defined by the insulation layer 253. The insulation layer 253 or the conductive layer 254 may have an end in contact with the conductive layer 134 of the circuit layer 13. Furthermore, the insulation layer 253 and the conductive layer 254 may each occupy a section of the surface 251 of the conductive through-via 25.

The material of the insulation layer 253 may include, for example, dielectric material, such as polyamide (PA), polyimide (PI), or the like. The material of the conductive layer 254 may include, for example, metal such as copper, aluminum, gold, titanium, and/or other suitable materials.

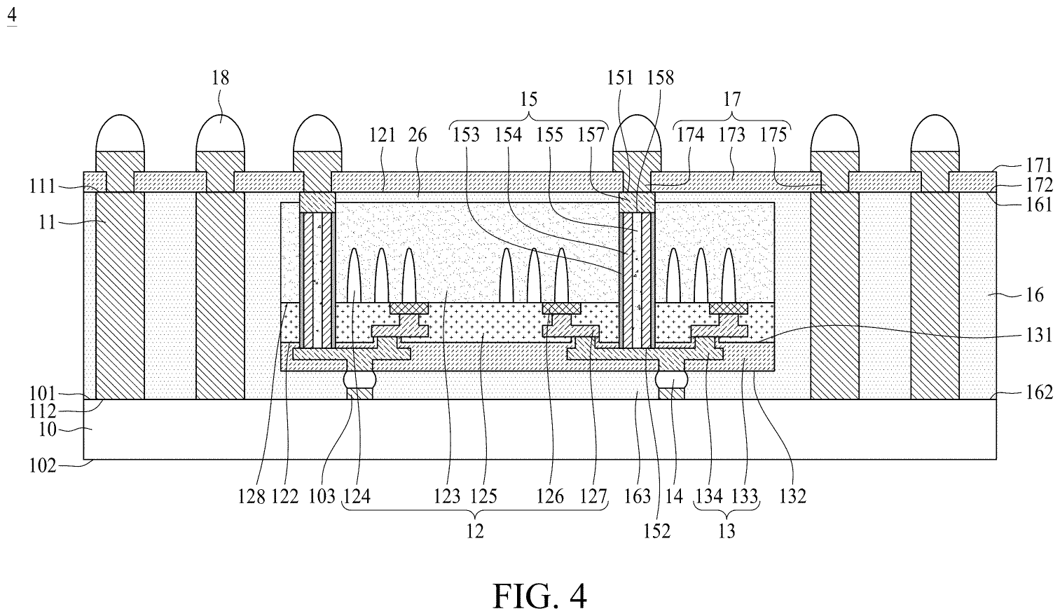

FIG. 4 illustrates a cross-sectional view of a semiconductor package structure 4 according to some embodiments of the present disclosure. The semiconductor package structure 4 is similar to the semiconductor package structure 1 of FIG. 1, except that the semiconductor package structure 4 further includes an encapsulant 26 disposed on the electronic component 12. The encapsulant 26 may include a material similar to the encapsulant 16. The encapsulant 16 and the encapsulant 26 may be formed at the same time. The conductive through-via 15 may include a portion, i.e., the passivation layer 153, the conductive layer 154, and the insulation 155, and a portion 157 extending through the encapsulant 26. The portion 157 may be adjacent to the surface 151 of the conductive through-via 15. The portion 157 may extend through a distance within the electronic component 12. The portion 153/154/155 and the portion 157 of the conductive through-via 15 may have an interface 158 within the electronic component 12. The material of the portion 157 may include, for example, metal such as copper, aluminum, gold, titanium, and/or other suitable materials.

In some embodiments, the portion 157 may be formed by forming a conductive layer in a hole extending through a portion of the encapsulant 26 and substantially aligned with the conductive through-via. The interface 158 may be formed between the conductive layer of the portion 157 and the portion 153/154/155 of the conductive through-via.

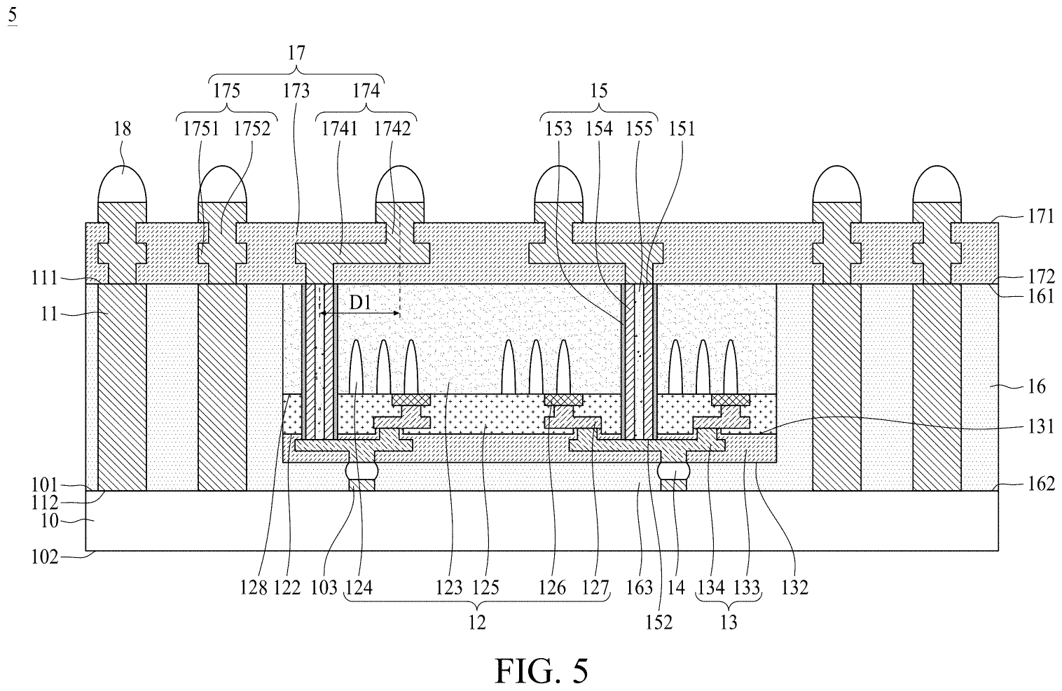

FIG. 5 illustrates a cross-sectional view of a semiconductor package structure 5 according to some embodiments of the present disclosure. The semiconductor package structure 5 is similar to the semiconductor package structure 1 of FIG. 1, except that the conductive layers 174 and 175 of the circuit layer 17 includes extending portions 1741, 1751, and a via portion 1742, 1752, respectively. The extending portions 1741 and 1751 may each extend in a direction parallel with the surface 151 of the conductive through-via 15. One of the connection elements 18 may be electrically connected to the conductive through-via 15 through the via portion 1741 and the extending portion 1742 of the conductive layer 174. As shown in FIG. 5, the connection element 18 (e.g., a center line thereof) is offset from the conductive through-via 15 (e.g., a center line thereof) by a distance D1 in the direction parallel with the surface 151 of the conductive through-via 15. One of the connection elements 18 may be electrically connected to the conductive pillar 11 through the via portion 1751 and the extending portion 1752 of the conductive layer 175.

The surface 152 of the conductive through-via 15 may be in contact with the conductive layer 127 of the electronic component 12. In alternative embodiments, the surface 152 of the conductive through-via 15 may be in contact with the conductive pad 126 of the electronic component 12. The surface 152 of the conductive through-via 15 and the interface between the body 123 and the passivation layer 125 may be substantially coplanar. In other words, the conductive through-via 15 may extend to the interface between the body 123 and the passivation layer 125 or be free from extending in the passivation 125. In some embodiments, the conductive layer 154 of the conductive through-via 15 may cover a portion of the conductive pad 126.

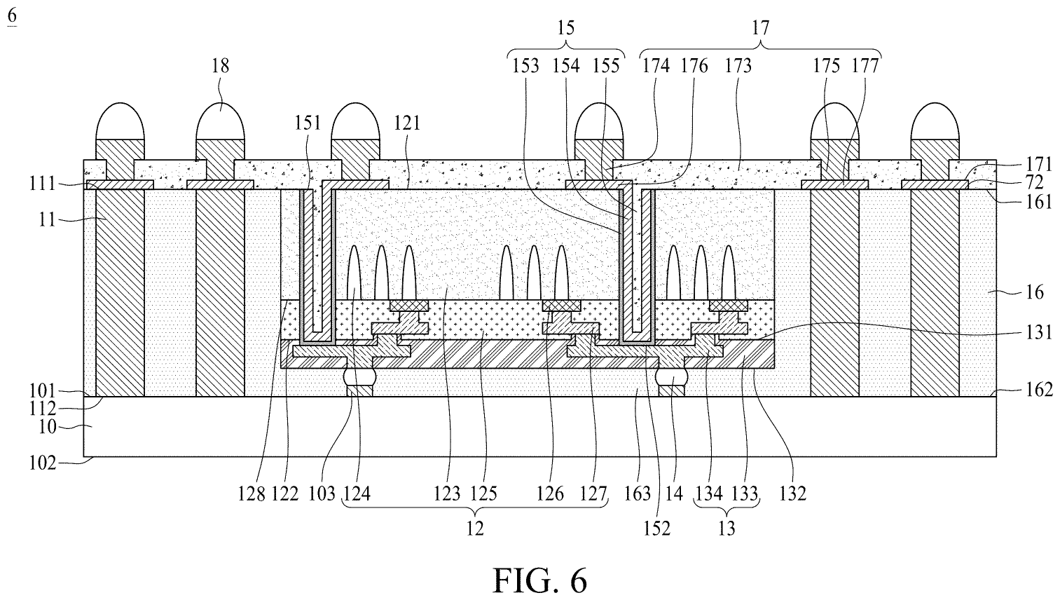

FIG. 6 illustrates a cross-sectional view of a semiconductor package structure 6 according to some embodiments of the present disclosure. The semiconductor package structure 6 is similar to the semiconductor package structure 1 of FIG. 1, except that the circuit layer 17 further includes a conductive layer 176 in contact with the conductive layer 154 of the conductive through-via 15 and a conductive layer 177 in contact with the conductive pillar 11. The conductive layers 154, 176, 177 may be formed in the same electroplating process or the same sputtering process. Furthermore, the passivation layer 173 of the circuit layer 17 may be in contact with the insulation layer 155 of the conductive through-via 15. The passivation layer 173 of the circuit layer 17 and the insulation layer 155 of the conductive through-via 15 may be formed simultaneously.

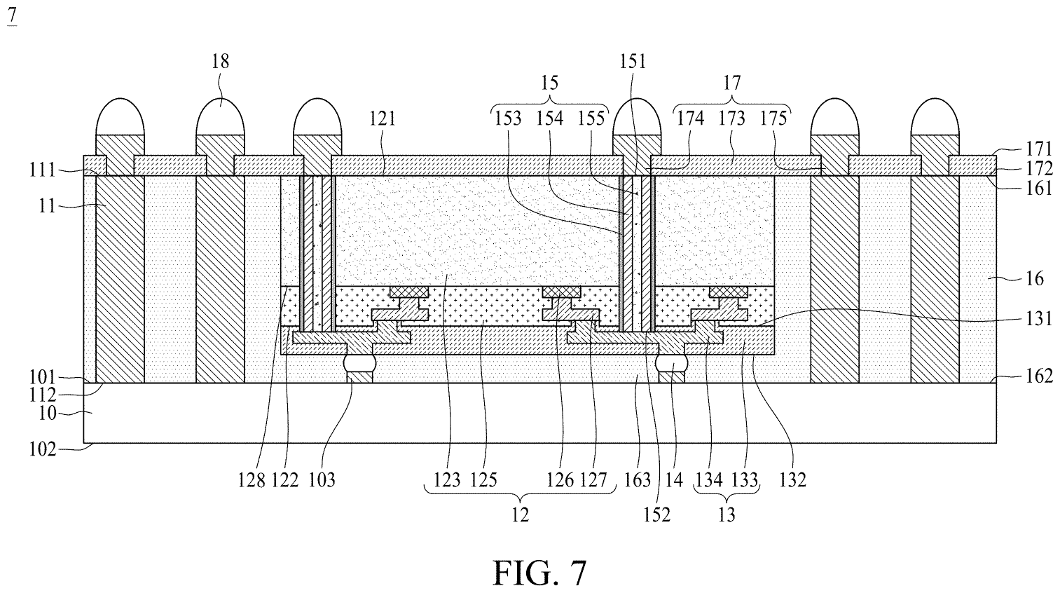

FIG. 7 illustrates a cross-sectional view of a semiconductor package structure 7 according to some embodiments of the present disclosure. The semiconductor package structure 7 is similar to the semiconductor package structure 1 of FIG. 1, except that the electronic component 12 may not include capacitors.

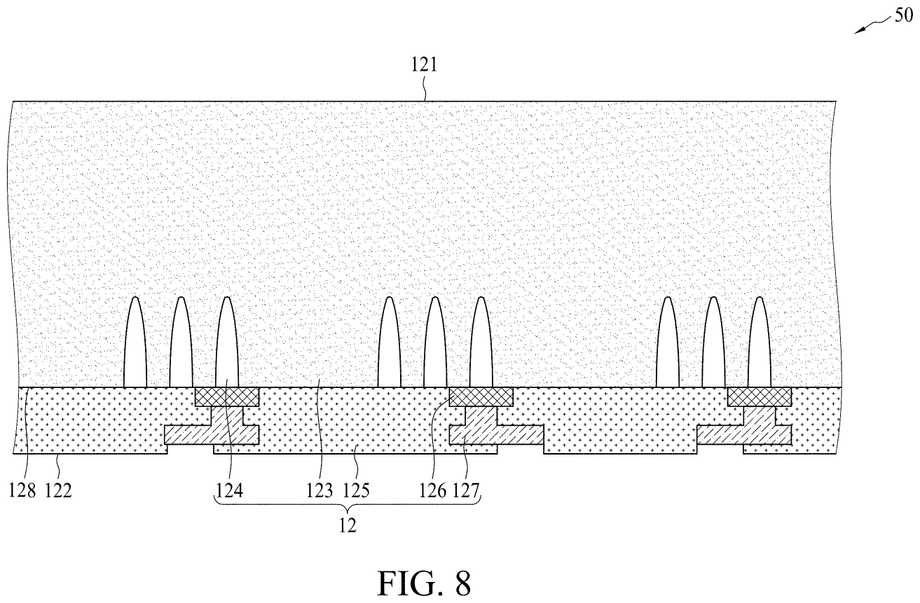

FIG. 8 through FIG. 17 illustrate a method for manufacturing a semiconductor package structure according to some embodiments of the present disclosure. In some embodiments, the method is for manufacturing the semiconductor package structure 1 shown in FIG. 1.

Referring to FIG. 8, a substrate 50 including a plurality of electronic components 12 is provided. The electronic component 12 may include a body 123 and a plurality of capacitors 124, a passivation layer 125, a plurality of conductive pads 126, and a plurality of conductive layers 127. A portion of the conductive layers 127 may be exposed from the passivation layer 125. The electronic component 12 may have a surface 121 and a surface 122 opposite to the surface 121. The body 123 may have a surface 128 and the surface 128 may be an active surface. An interface is formed between the body 123 and the passivation layer 125. The interface therebetween and the surface 128 may be substantially coplanar.

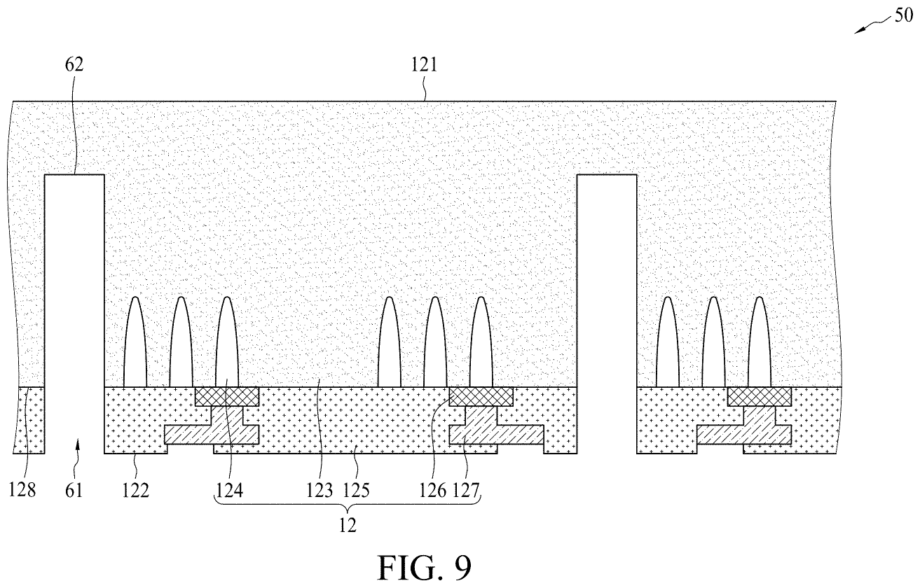

Referring to FIG. 9, a hole 61 is formed in the electronic component 12 by, for example, an etching process. The hole 61 may extend a distance in the electronic component 12 from the surface 122 and may have a bottom surface 62 within the electronic component 12. The hole 61 may extend through the interface between the body 123 and the passivation layer 125.

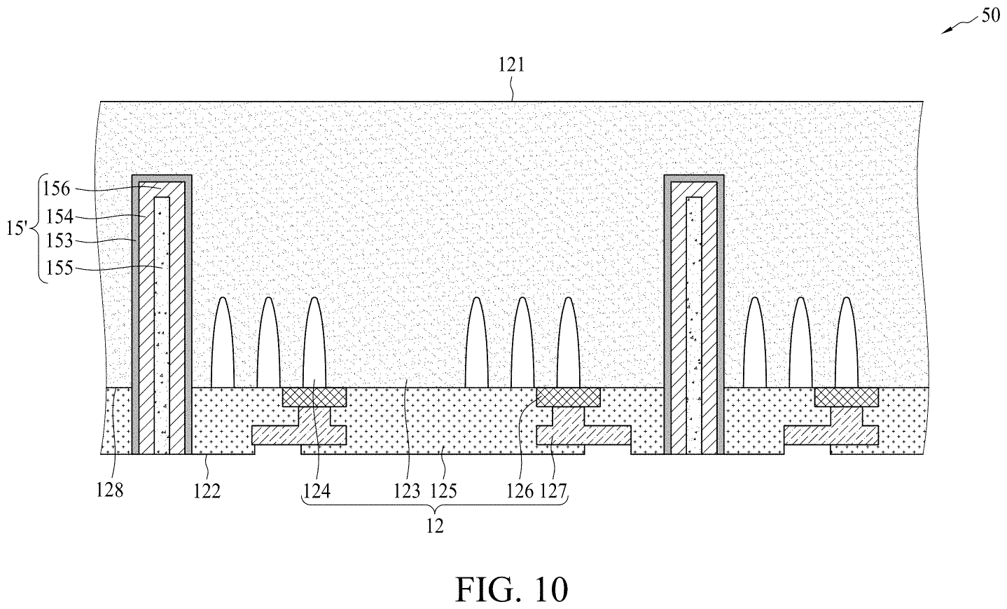

Referring to FIG. 10, a passivation layer 153, a conductive layer 154, and an insulation layer 155 may be sequentially formed in the hole 61 by, for example, a sputtering process followed by a removal process to form a conductive through-via structure 15′. For example, the insulation layer 155 may be formed in a space defined by the conductive layer 154. The conductive through-via structure 15′ further includes a portion 156 adjacent to the bottom of the conductive through-via structure 15′.

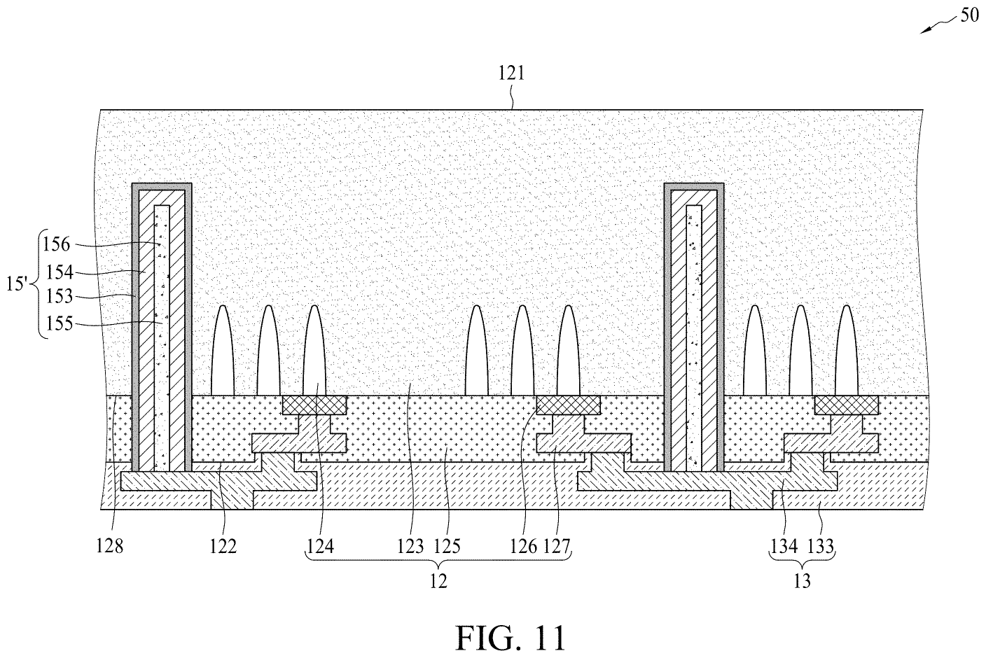

Referring to FIG. 11, a circuit layer 13 may be formed on the surface 122 of the electronic component 12. The circuit layer 13 may include a passivation 133 and a plurality of conductive layers 134. The conductive layer 134 may be in contact with the exposed portion of the conductive layer 127. The conductive through-via structure 15′ may be in contact with the conductive layer 134. Afterwards, the substrate 50 may be singulated to physically separate the plurality of electronic components 12. The smooth surface, e.g., the surface 121 and the surface 122 of the electronic component 12 can reduce the risk of cracking during the singulation process of the substrate 50.

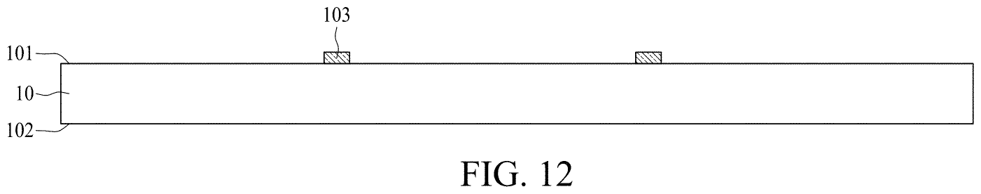

Referring to FIG. 12, an electronic component 10 is provided. The electronic component 10 may include a surface 101 and a surface 102 opposite to the surface 101. The electronic component 10 may include a plurality of conductive pads 103 on the surface 101.

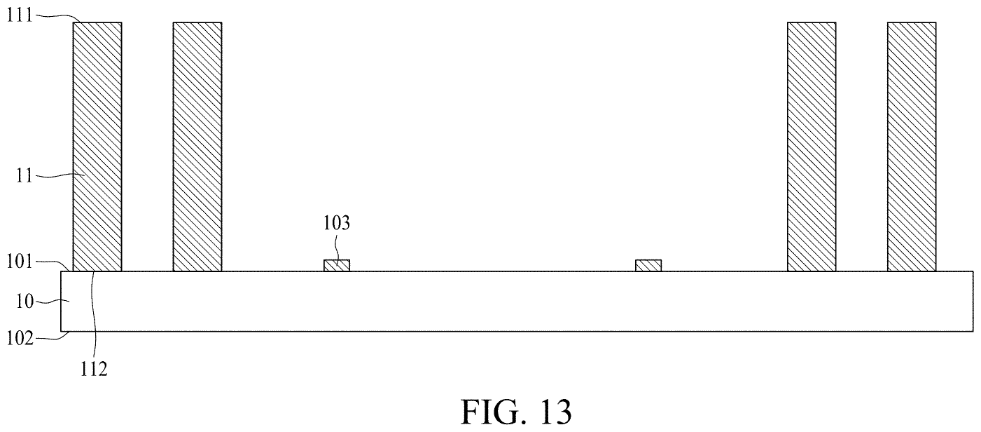

Referring to FIG. 13, a plurality of conductive pillar 11 is formed on the surface 101 of the electronic component 10 by, for example, an electroplating process. The conductive pillar 11 may include a surface 111 facing away from the electronic component 10 and a surface 112 facing toward the electronic component 10.

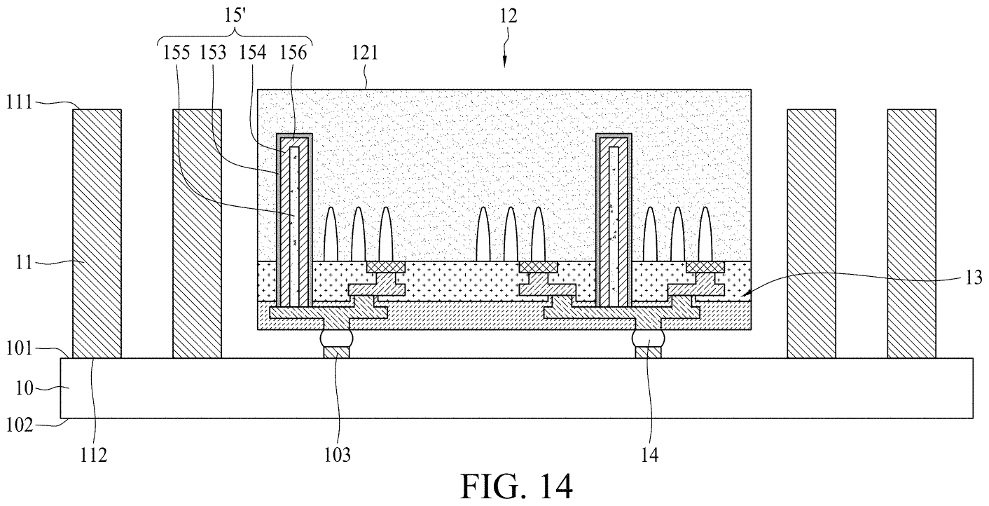

Referring to FIG. 14, the electronic component 12 of FIG. 11 is attached to (or bonded on) the conductive pads 103 of the electronic component 10 through a plurality of electrical connection elements 14.

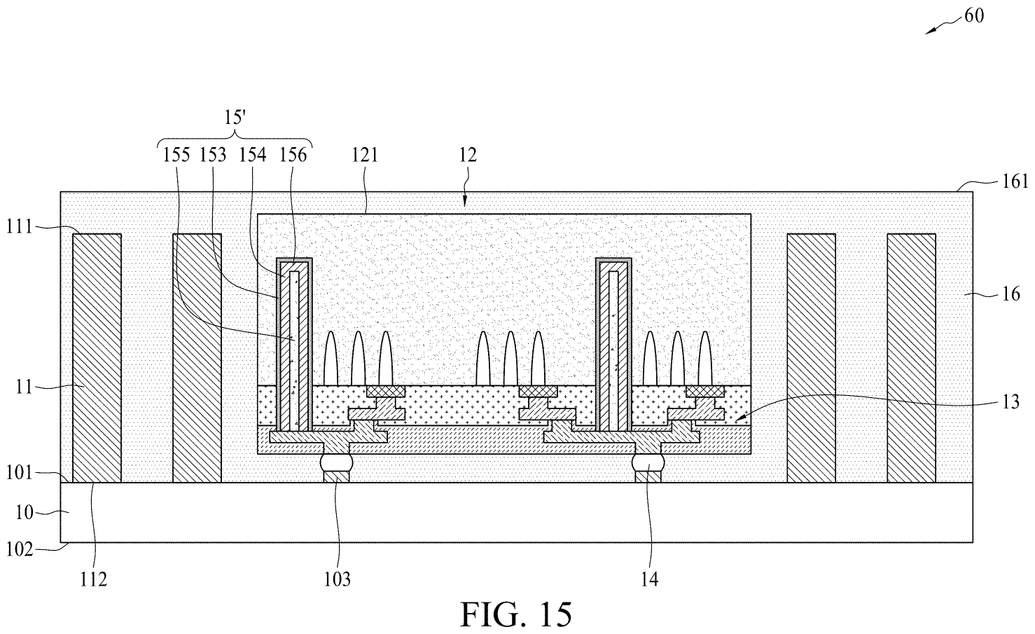

Referring to FIG. 15, an encapsulant 16 is formed on the surface 101 of the electronic component 10. The encapsulant 16 may surround the conductive pillars 11 and the electronic component 12. The encapsulant 16 may encapsulate the conductive pillars 11 and the electronic component 12. The encapsulant 16 may have a surface 161 facing away from the electronic component 10 and at a higher elevation relative to a reference plane (e.g., the surface 101) than the surface 111 and the surface 121.

As shown in FIG. 15, a semiconductor package structure 60 is provided. The semiconductor package structure 60 may include the electronic component 10, the conductive pillar 11 on the electronic component 10, the electronic component 12 on the electronic component 10, and the encapsulant 16 surrounding the conductive pillar 11 and the electronic component 12. The electronic component 12 has the conductive through via 15 extending therethrough.

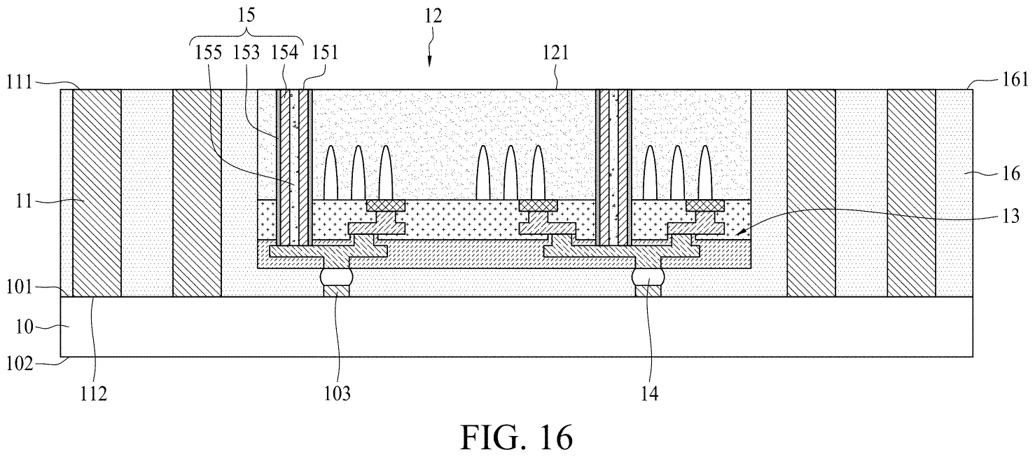

Referring to FIG. 16, a portion of the encapsulant 16 may be removed from the surface 161 of the encapsulant 16 by, for example, a thinning process. A portion of the conductive pillar 11 may be removed from the surface 111 of the conductive pillar 11 by, for example, a thinning process. A portion of the electronic component 12 may be removed from the surface 121 of the encapsulant 12 by, for example, a thinning process. Furthermore, a portion of the conductive through-via structure 15′, e.g., the portion 156, may be removed by, for example, a thinning process to form a conductive through-via 15. The thinning process may include, for example a grinding process. In some embodiments, the encapsulant 16, the electronic component 12, and the conductive pillar 11 may be thinned (e.g., ground) in the same direction. In some embodiments, the encapsulant 16, the electronic component 12, the conductive pillar 11, and conductive through-via structure 15 may be ground in the same process.

In some embodiments, a molding film is formed on the encapsulant 16 prior to the thinning processes as discussed above.

The conductive through-via 15 may have a surface 151 facing away from the electronic component 10 and a surface 152 facing toward the electronic component 10. As shown in FIG. 16, the surface 151 of the conductive through-via 15 and the surface 111 of the conductive pillar 11 may be substantially coplanar. Furthermore, the surfaces 111, 121, 151, 161 may be substantially coplanar.

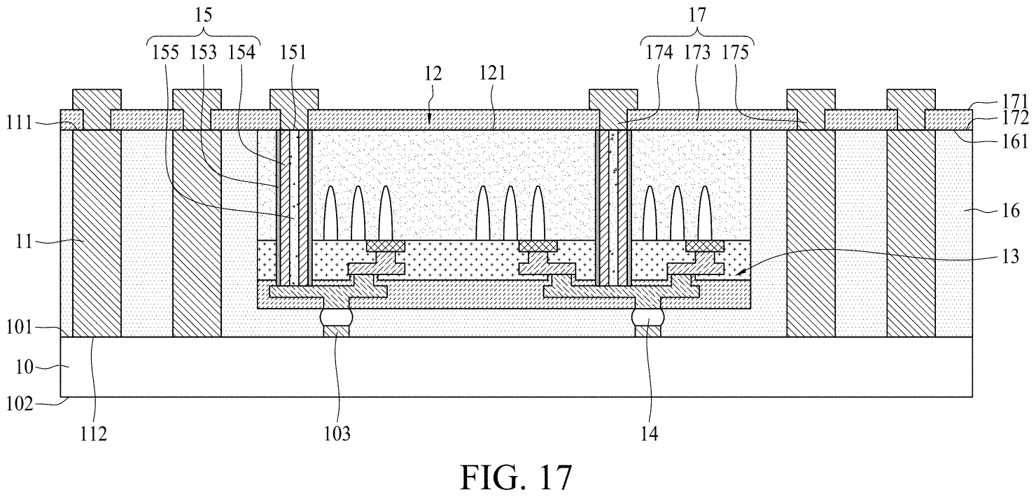

Referring to FIG. 17, a circuit layer 17 may be formed on the substantially coplanar surfaces (e.g., the surfaces 111, 121, 151, 161). In some alternative embodiments, an electronic component and conductive pillars may have a height difference, such that extra electrical connection structures are formed on the backside of the electronic component to compensate for the height difference. In the present disclosure, since the surfaces 111, 121, 151, 161 are at the same elevation relative to a reference plane (e.g., the surface 101), no extra electrical connection structure for the height compensation is needed. Thus, the manufacturing process of the semiconductor package structure can be simplified and the cost can be reduced. Furthermore, the total height of the semiconductor package structure can be reduced.

The circuit layer 17 may include a passivation layer 173, a plurality of conductive layers 174 electrically connected to the conductive through-via 15, and a plurality of conductive layers 175 electrically connected to the conductive pillar 11.

Afterwards, a plurality of electrical connection elements 18 may be formed on the circuit layer 17 to form the semiconductor package structure 1 as illustrated in FIG. 1.

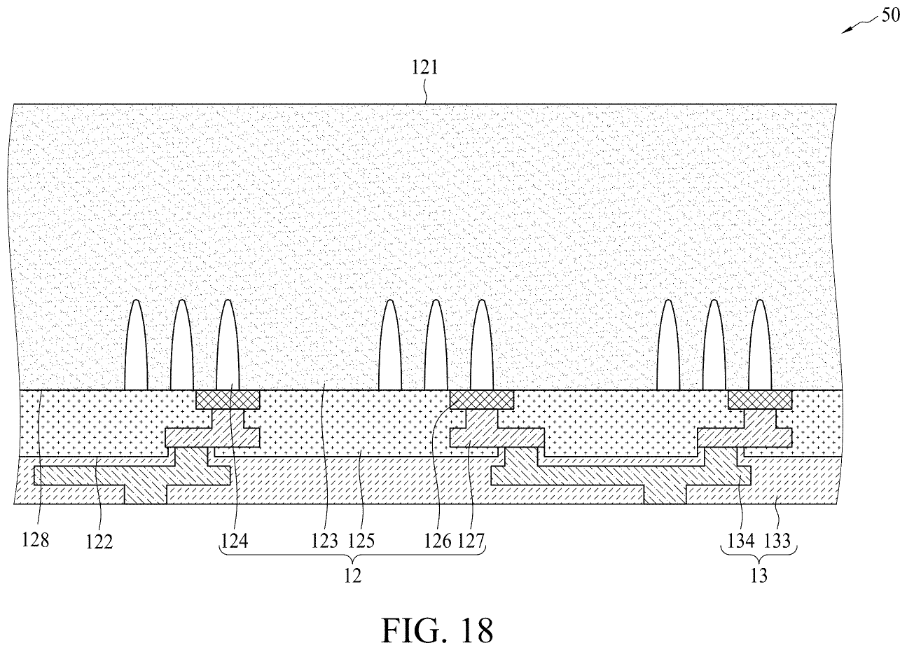

FIG. 18 through FIG. 22 illustrate a method for manufacturing a semiconductor package structure according to some embodiments of the present disclosure. In some embodiments, the method is for manufacturing the semiconductor package structure 2 shown in FIG. 2.

Referring to FIG. 18, a substrate 50 with a plurality of electronic components 12 is provided. The electronic component 12 may include a body 123 and a plurality of capacitors 124, a passivation layer 125, a plurality of conductive pads 126, and a plurality of conductive layers 127. The electronic component 12 may have a surface 121 and a surface 122 opposite to the surface 121. A circuit layer 13 is formed on the surface 122 of the electronic component 12. The circuit layer 13 may include a passivation layer 133 and a plurality of conductive layers 134. The conductive layer 134 may be in contact with the conductive layer 127.

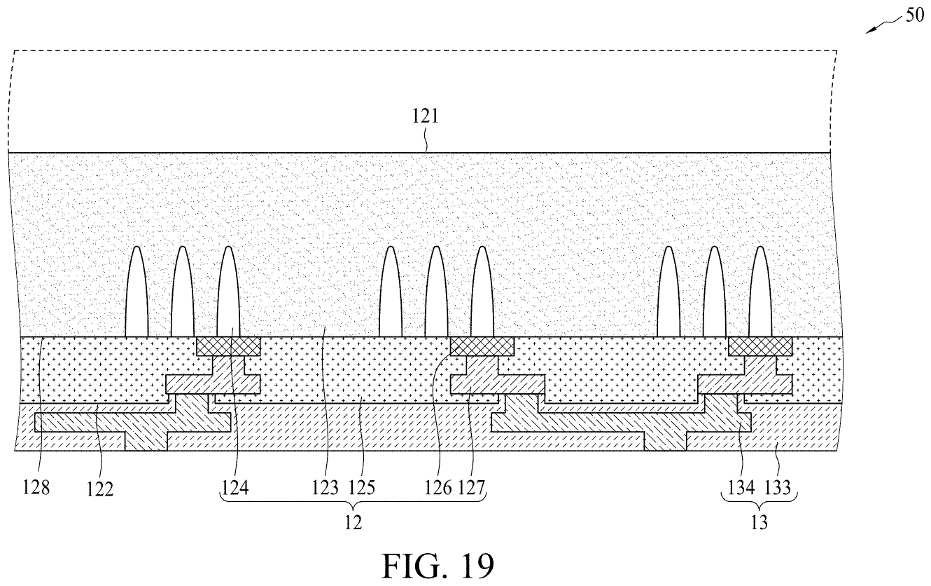

Referring to FIG. 19, a portion of the electronic component 12 may be removed from the surface 121 of the electronic component 12 by, for example, a thinning process.

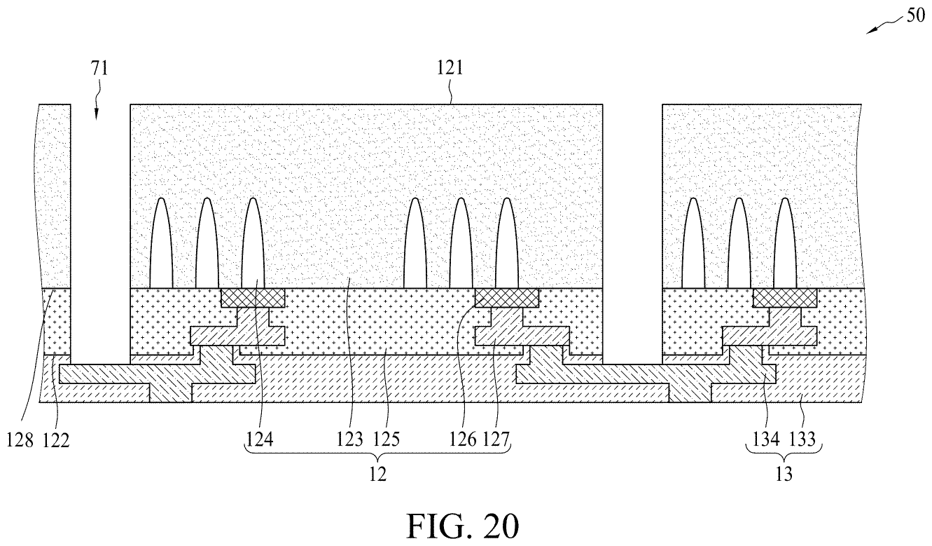

Referring to FIG. 20, a hole 71 is formed in the electronic component 12 by, for example, an etching process. The hole 71 may extend from the surface 121 to the conductive layer 134 of the circuit layer 13. Thus, a portion of the conductive layer 134 is exposed from the hole 71.

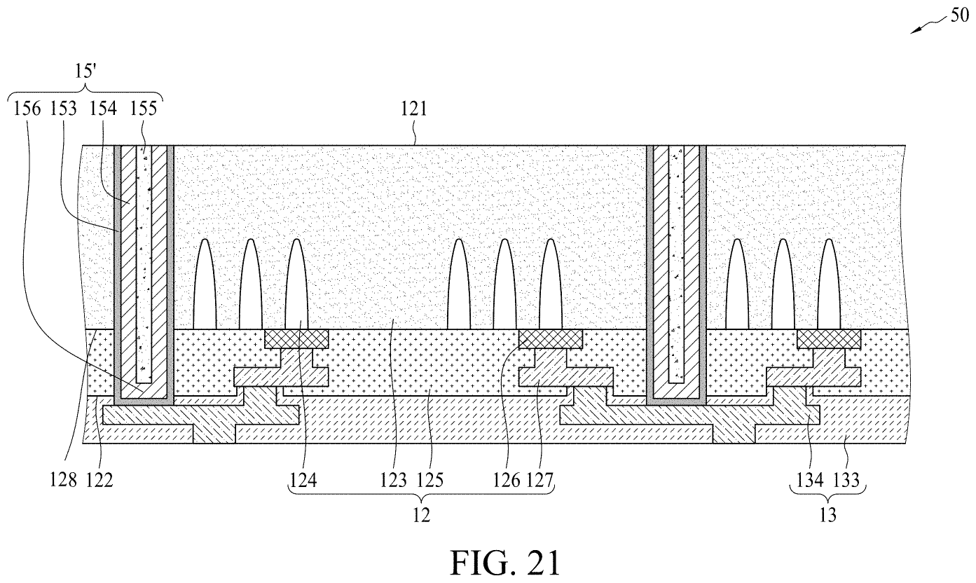

Referring to FIG. 21, a passivation layer 153, a conductive layer 154, and an insulation layer 155 may be sequentially formed in the hole 71 by, for example, a sputtering process followed by a removal process to form a conductive through-via structure 15′. The conductive through-via structure 15′ further includes a portion 156 adjacent to the conductive layer 134 of the circuit layer 13. Afterwards, the substrate 50 may be singulated to physically separate the plurality of electronic components 12.

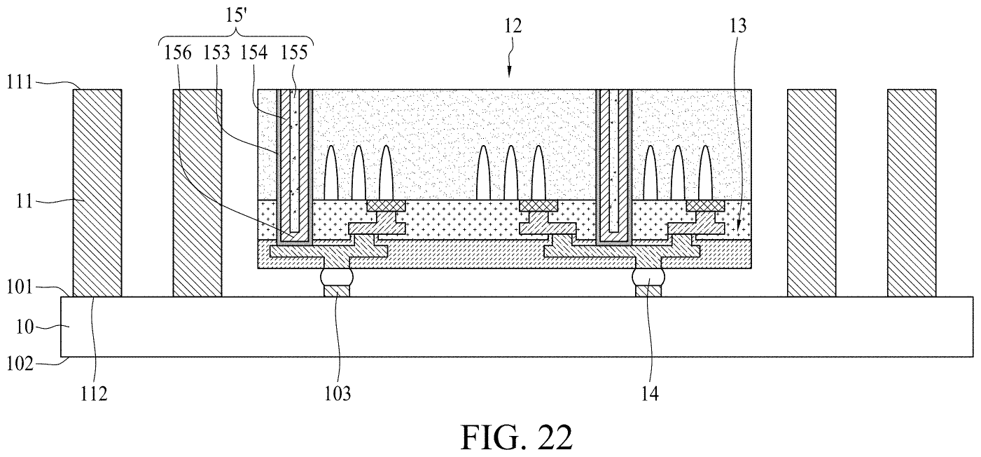

Referring to FIG. 22, the electronic component 12 of FIG. 21 is attached to (or bonded on) the conductive pads 103 of the electronic component 10 through the plurality of electrical connection elements 14. Afterwards, similar processes as illustrated in FIG. 15-17 may be performed to form the semiconductor package structure as illustrated in FIG. 2.

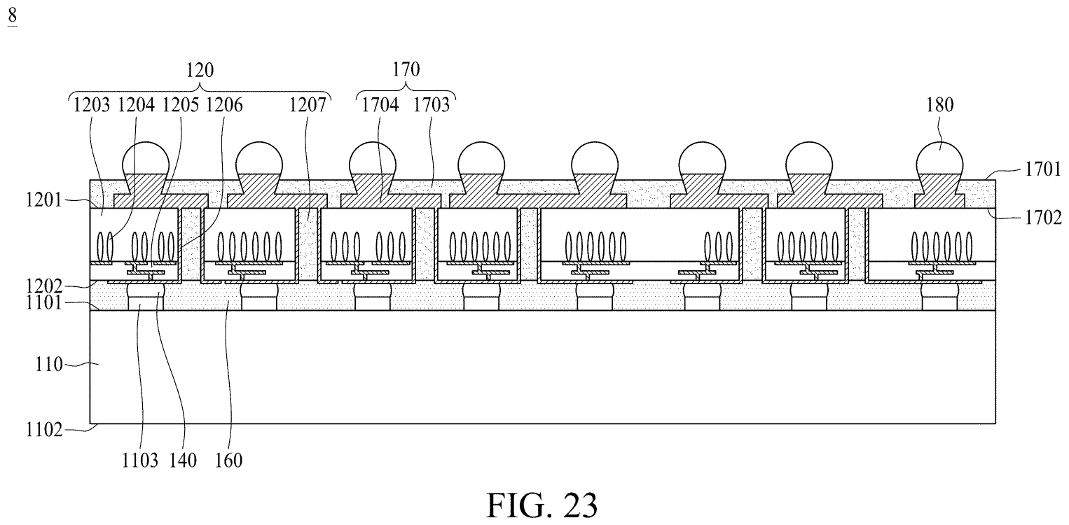

FIG. 23 illustrates a cross-sectional view of a semiconductor package structure 8 according to some embodiments of the present disclosure. The semiconductor package structure 8 may include an electronic component 110, an electronic component 120, a plurality of electrical connection elements 140, an underfill material, a circuit layer 170, and a plurality of electrical connection elements 180.

The electronic component 110 may have a surface 1101 and a surface 1102 opposite to the surface 1101. The electronic component 110 may include a plurality of conductive pads 1103 on the surface 1101. In some embodiments, the electronic component 110 may be a chip or a die including a semiconductor substrate, one or more integrated circuit devices and one or more overlying interconnection structures therein. The integrated circuit devices may include active devices such as transistors and/or passive devices such resistors, capacitors, inductors, or a combination thereof. For example, the electronic component 110 may include, for example, a processor, logic die, application specific integrated circuit (ASIC), an input/output device, etc.

The electronic component 120 is disposed on the surface 1101 of the electronic component 110. The electronic component 120 may be electrically connected to the electronic component 110 through the electrical connection elements 140. The electronic component 120 may have a size similar to the electronic component 110. The electrical connection element 140 may include, for example, a solder ball or a controlled collapse chip connection (C4) bump.

In some embodiments, the electronic component 120 may be a chip or a die including a semiconductor substrate, one or more integrated circuit devices and one or more overlying interconnection structures therein. The integrated circuit devices may include active devices such as transistors and/or passive devices such resistors, capacitors, inductors, or a combination thereof. For example, the electronic component 120 may include, for example, a de-coupling circuit, a memory device, etc.

The electronic component 120 may have a surface 1201 facing away from the electronic component 110 and a surface 1202 facing toward the electronic component 110. The electronic component 120 may include a plurality of bodies 1203, a plurality of capacitors 1204, a circuit layer 1205, a plurality of electrical connection structures 1206, and a dielectric layer 1207. The capacitors 1204 may be disposed in the body 1203 and adjacent to the circuit layer 1205. The circuit layer 1205 (e.g., a built-up circuit layer) may include a passivation layer and a plurality of conductive layers. The capacitors 1204 may be electrically connected to conductive layers of the circuit layer 1205. The electrical connection structures 1206 may have a through-via extending through the dielectric layer 1207 and an extending portion disposed on the surface 1202 of the electronic component 120. The electrical connection structures 1206 may be electrically connected to the conductive layers of the circuit layer 1205.

The material of the bodies 1203 may include, for example, silicon, doped-silicon, silicon-oxide, or silicon-nitride or other semiconductor materials. The material of the capacitors 1204 may include a dielectric, such as oxide, and/or a conductive material, such as polysilicon or metal. The material of the passivation layer of the circuit layer may include, for example, a molding compound, pre-impregnated composite fiber, borophosphosilicate (BPSG), silicon oxide, silicon oxynitride, or the like. The material of the conductive layer of the circuit layer 1205, electrical connection structures 1206 may each include, for example, metal such as copper, aluminum, gold, and/or other suitable materials. The material of the dielectric layer 1207 may include, for example, an organic material, such as a solder mask, a PI, an ABF, one or more molding compounds. The material of the dielectric layer 1207 may include, for example, an inorganic material silicon-oxide (SiOₓ), or a silicon-nitride (SiNₓ).

The circuit layer 170 is disposed on the surface 1201 of the electronic component 120. The circuit layer 170 may have a surface 1701 facing away from the electronic component 110 and a surface 1702 facing toward the electronic component 110. The circuit layer 17 may include a passivation layer 1703 and a plurality of conductive layers 1704 disposed in the passivation layer 1703. The conductive layers 1704 may include a protruding portion on the surface 1701 of the circuit layer 170. The electrical connection elements 180 may be electrically connected to the electrical connection structure 1206 through the conductive layer 1704 of the circuit layer 17. In some embodiments, the electrical connection elements 180 may be electrically connected to external circuitry. The electronic component 110 may be electrically connected to external circuitry through the electrical connection elements 180 and the electrical connection structure 1206.

The material of the passivation layer 1703 may include, for example, a molding compound, pre-impregnated composite fiber, borophosphosilicate (BPSG), silicon oxide, silicon oxynitride, or the like. The material of the conductive layers 1704 may include, for example, metal such as copper, aluminum, gold, and/or other suitable materials. The electrical connection element 180 may include, for example, a solder ball or a controlled collapse chip connection (C4) bump.

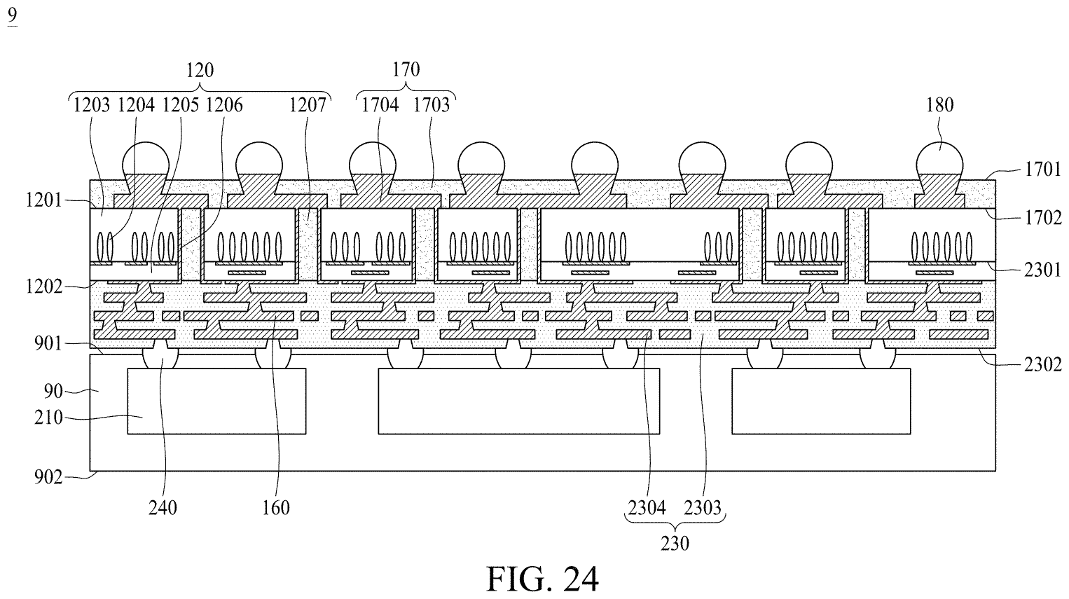

FIG. 24 illustrates a cross-sectional view of a semiconductor package structure 9 according to some embodiments of the present disclosure. The semiconductor package structure 9 may include an electronic component 120, a circuit layer 170, a plurality of electrical connection elements 180, a plurality of electronic components 210, a circuit layer 230, a plurality of electrical connection elements 240, and an encapsulant 90.

The electronic component 120, the circuit layer 170, and the electrical connection elements 180 of the semiconductor package structure 9 may be similar to electronic component 120, the circuit layer 170, and the electrical connection elements 180 of the semiconductor package structure 8 of FIG. 23.

The electronic components 210 may be encapsulated by the encapsulant 90. The encapsulant 90 may have a surface 901 and a surface 902 opposite to the surface 901. In some embodiments, the electronic components 210 may be covered by the surface 902. Alternatively, the electronic components 210 may be exposed from the surface 902.

The electronic components 210 may be electrically connected to the circuit layer 230 through the electrical connection elements 240. Each of the electronic components 210 may have different size. The electrical connection element 240 may include, for example, a solder ball or a controlled collapse chip connection (C4) bump.

In some embodiments, the electronic components 210 may each be a chip or a die including a semiconductor substrate, one or more integrated circuit devices and one or more overlying interconnection structures therein. The integrated circuit devices may include active devices such as transistors and/or passive devices such resistors, capacitors, inductors, or a combination thereof. For example, the electronic components 210 may each include, for example, a processor, logic die, application specific integrated circuit (ASIC), an input/output device, etc.

The circuit layer 230 is disposed between the electronic components 210 and the electronic component 120. The circuit layer 230 may have a surface 2301 facing away from the electronic components 210 and a surface 2302 facing toward the electronic components 210. The circuit layer 230 may include a passivation layer 2303 and a plurality of conductive layers 2304. The conductive layers 2304 may be disposed in the passivation layer 2303. The conductive layer 2304 of the circuit layer 230 may be electrically connected to the electronic components 210 through the electrical connection elements 240. The conductive layers 2304 of the circuit layer 230 may be electrically connected to the electronic component 120. The electronic component 120 may be electrically connected to the electronic components 210 through the circuit layer 230. The electronic components 210 may be electrically connected to external circuitry through the circuit layer 230, the electrical connection structure 1206, the circuit layer 170, and the electrical connection elements 180.

The material of the passivation layer 2303 may include, for example, a molding compound, pre-impregnated composite fiber, borophosphosilicate (BPSG), silicon oxide, silicon oxynitride, or the like. The material of the conductive layers 2304 may include, for example, metal such as copper, aluminum, gold, and/or other suitable materials. The encapsulant 90 may include, for example, an epoxy resin having fillers, a molding compound (e.g., an epoxy molding compound or other molding compound), a polyimide, a phenolic compound or material, a material with a silicone dispersed therein, or a combination thereof.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same or equal if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

Two surfaces can be deemed to be coplanar or substantially coplanar if a displacement between the two surfaces is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

1. A semiconductor package structure, comprising:
a first electronic component;
a conductive pillar disposed on the first electronic component and having a first surface facing away from the first electronic component;
a second electronic component disposed on the first electronic component; and
a conductive through via extending through the second electronic component and having a first surface facing away from the first electronic component,
wherein the first surface of the conductive through via and the first surface of the conductive pillar are substantially coplanar.

2. The semiconductor package structure of claim 1, wherein the second electronic component has a first surface facing away from the first electronic component, and the first surface of the second electronic component and the first surface of the conductive pillar are substantially coplanar.

3. The semiconductor package structure of claim 1, further comprising a first circuit layer disposed on the conductive pillar and the second electronic component.

4. The semiconductor package structure of claim 3, further comprising a second circuit layer disposed between the first electronic component and the second electronic component.

5. The semiconductor package structure of claim 4, wherein the second circuit layer is in contact with a second surface of the conductive through via facing toward the first electronic component.

6. The semiconductor package structure of claim 3, wherein the first circuit layer comprises a conductive layer extending in the direction parallel with the first surface of the conductive through via.

7. The semiconductor package structure of claim 1, further comprising an encapsulant disposed on the first electronic component and surrounding the second electronic component and the conductive pillar, wherein the encapsulant has a first surface substantially at the same elevation with the first surface of the conductive through via.

8-9. (canceled)

10. The semiconductor package structure of claim 1, wherein the second electronic component comprises one or more capacitors, wherein the capacitors are electrically connected to the first electronic component.

11. The semiconductor package structure of claim 10, wherein the second electronic component comprises a body having an active surface facing toward the first electronic component, and wherein the capacitors are adjacent to the active surface of the body.

12. The semiconductor package structure of claim 1, wherein the second electronic component comprises a body and a passivation layer, and wherein the conductive through-via extends through an interface between the body and the passivation layer.

13. The semiconductor package structure of claim 1, wherein the second electronic component comprises a body having an active surface facing toward the first electronic component, and the second electronic component comprises a conductive pad adjacent to the active surface, wherein the conductive pad is in contact with the conductive through via.

14-20. (canceled)

21. The semiconductor package structure of claim 1, wherein the first circuit layer comprises a conductive layer disposed on the conductive through via, and wherein a width of the conductive through via is greater than a width of the conductive layer of the first circuit layer.

22. The semiconductor package structure of claim 1, wherein the conductive through via includes a passivation layer and a conductive layer surrounding the passivation layer.

23. The semiconductor package structure of claim 22, wherein the conductive through via includes an insulation layer surrounding the conductive layer.

24. The semiconductor package structure of claim 23, wherein each of the passivation layer, the conductive layer, and the insulation layer has a first surface facing away from the first electronic component, and wherein the first surfaces of the passivation layer, the conductive layer, and the insulation layer are substantially coplanar.

25. The semiconductor package structure of claim 24, wherein each of the passivation layer, the conductive layer, and the insulation layer has a second surface facing toward the first electronic component, and wherein the second surfaces of the passivation layer, the conductive layer, and the insulation layer are substantially coplanar.

26. The semiconductor package structure of claim 1, wherein the conductive through via includes a conductive layer and an insulation layer disposed along a sidewall of the conductive through via, wherein the conductive layer fills in the space defined by the insulation layer.

27. The semiconductor package structure of claim 1, wherein the first surface of the conductive pillar has a first roughness and the first surface of the conductive through via has a second roughness substantially the same as the first roughness.

28. The semiconductor package structure of claim 5, wherein the second circuit layer includes a passivation layer and a conductive layer embedded in the passivation layer, wherein the conductive layer of the second circuit layer is in contact with a second surface of the conductive through via facing toward the first electronic component.

29. The semiconductor package structure of claim 1, wherein the first circuit layer is electrically connected to the conductive through via and the conductive pillar.
